(19) United States
(12) Patent Application Publication
(10) Pub. No.: US 2025/0234750 A1
(43) Pub. Date: Jul. 17, 2025

(54) DISPLAY DEVICE AND METHOD FOR MANUFACTURING THE SAME

(71) Applicant: Samsung Display Co., Ltd., Yongin-si (KR)

(72) Inventors: JONGHYEON CHOI, Yongin-si (KR); JEONGHO HWANG, Yongin-si (KR)

(21) Appl. No.: 18/957,891

(22) Filed: Nov. 25, 2024

(30) Foreign Application Priority Data
Jan. 15, 2024 (KR) 10-2024-0006142

(51) Int. Cl. H10K 59/80

(52) U.S. Cl. CPC H10K 59/871

(57) ABSTRACT

A method for manufacturing a display device includes: providing a first stage, forming a coating material on the first stage, adsorbing a target member onto a second stage, forming a jig on the first stage, placing the second stage on the jig, curing the coating material to form a preliminary coating member, and cutting the preliminary coating member to form a coating member.

This application claims priority to Korean Patent Application No. 10-2024-0006142, filed on Jan. 15, 2024, and all the benefits accruing therefrom under 35 U.S.C. § 119, the content of which in its entirety is herein incorporated by reference.

### BACKGROUND

Embodiments of the present disclosure described herein relate to a display device and a method for manufacturing the same, and more particularly, relate to a display device including a coating member with a constant thickness and a method for manufacturing the same.

A display device such as a smart phone, a digital camera, a laptop computer, a navigation system, and a smart television may include a display panel, an optical film, a protective substrate, and a window. The protective substrate and/or the window may be formed via a curing process of a coating material.

### SUMMARY

Embodiments of the present disclosure provide a display device including a coating member with a constant thickness and a method for manufacturing the same.

According to an embodiment, a method for manufacturing a display device includes: providing a first stage, forming a coating material on the first stage, adsorbing a target member onto a second stage, forming a jig on the first stage, placing the second stage on the jig, curing the coating material to form a preliminary coating member, and cutting the preliminary coating member to form a coating member.

In one implementation, the forming of the jig on the first stage may include setting a height of the jig to be the same as or greater than a sum of a thickness of the preliminary coating member and a thickness of the target member.

In one implementation, the cutting of the preliminary coating member to form the coating member may include cutting a portion of the preliminary coating member protruding from a side surface of the target member.

In one implementation, the first stage may contain a transparent material.

In one implementation, the method may further include forming a protective layer containing polyethylene terephthalate (“PET”) on the first stage.

In one implementation, the curing of the coating material to form the preliminary coating member may include irradiating ultraviolet (“UV”) laser toward the first stage.

In one implementation, the target member may be a display panel, and the coating member may be a protective substrate.

In one implementation, the cutting of the preliminary coating member to form the coating member may include cutting the preliminary coating member such that a side surface of the display panel is aligned with a side surface of the protective substrate.

In one implementation, the method may further include forming an optical film on the coating member.

In one implementation, the target member may be an optical film, and the coating member may be a window.

In one implementation, the cutting of the preliminary coating member to form the coating member may include cutting the preliminary coating member such that a side surface of the optical film is aligned with a side surface of the window.

In one implementation, the first stage may contain a heat-conducting material.

In one implementation, the method may further include preparing an optical film member including a first release film, an optical film, and a second release film, which are sequentially stacked, and removing the second release film and placing the first release film and the optical film on the first stage, and a width in one direction of the first release film may be greater than a width in the one direction of the optical film.

In one implementation, the method may further include forming the preliminary coating member and then removing the first release film.

In one implementation, the forming of the coating material on the first stage may include depositing the coating material to cover a front surface of the optical film.

In one implementation, a top surface of the optical film may be aligned with a top surface of the coating member.

In one implementation, the curing of the coating material to form the preliminary coating member may include supplying heat to the first stage.

According to another embodiment, a display device includes a display panel, a protective substrate disposed on the display panel, and an optical film disposed on the protective substrate, and a top surface of the protective substrate is aligned with a top surface of the optical film.

In one implementation, a side surface of the protective substrate may be aligned with a side surface of the display panel.

In one implementation, the protective substrate may be directly bonded with the display panel and the optical film.

### BRIEF DESCRIPTION OF THE FIGURES

The above and other aspects and features of the present disclosure will become apparent by describing in detail embodiments thereof with reference to the accompanying drawings.

FIG. 1 is a perspective view of a display device according to an embodiment of the present disclosure.

FIG. 2 is a schematic cross-sectional view of a display device according to Comparative Example of the present disclosure.

FIG. 3 is a schematic cross-sectional view of a display device according to an embodiment of the present disclosure.

FIG. 4 is a schematic cross-sectional view of a display device according to another embodiment of the present disclosure.

FIG. 5 is a cross-sectional view of a display panel according to an embodiment of the present disclosure.

FIGS. 6A to 6F are cross-sectional views showing some of steps of a display device manufacturing method according to an embodiment of the present disclosure.

FIGS. 7A to 7G are cross-sectional views showing some of steps of a display device manufacturing method according to an embodiment of the present disclosure.

### DETAILED DESCRIPTION

As used herein, when a component (or a region, a layer, a portion, and the like) is referred to as being “on”, “connected to”, or “coupled to” another component, it means that the component may be directly disposed/connected/coupled on another component or a third component may be disposed between the component and another component.

Like reference numerals refer to like components. In addition, in the drawings, thicknesses, ratios, and dimensions of components are exaggerated for effective description of technical content. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” “and/or” includes all of one or more combinations that the associated components may define.

Terms such as “first”, “second”, and the like may be used to describe various components, but the components should not be limited by the terms. The above terms are used only for the purpose of distinguishing one component from another. For example, without departing from the scope of the present disclosure, a first component may be named as a second component, and similarly, the second component may also be named as the first component. The singular expression includes the plural expression unless the context clearly dictates otherwise.

In addition, terms such as “beneath”, “below”, “on”, “above” are used to describe the relationship of the components illustrated in the drawings. The above terms are relative concepts and are described with reference to directions indicated in the drawings. As used herein, “disposed on” may refer to being disposed not only on top of but also beneath a member.

It should be understood that terms such as “include” or “have” are intended to specify that a feature, a number, a step, an operation, a component, a part, or a combination thereof described herein is present, and do not preclude a possibility of addition or existence of one or more other features or numbers, steps, operations, components, parts, or combinations thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to the drawings.

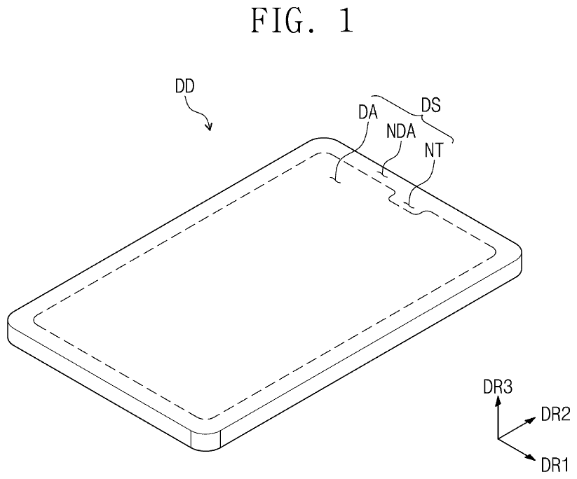

FIG. 1 is a perspective view of a display device DD according to an embodiment of the present disclosure.

Referring to FIG. 1, the display device DD may be a device that is activated in response to an electrical signal and displays an image. The display device DD may include various embodiments that provide the image to various users. For example, the display device DD may not only be a large device such as a television, an external billboard, and the like, but also a small or medium-sized device such as a monitor, a mobile phone, a tablet computer, a navigation system, a game console, and the like. The embodiments of the display device DD are merely illustrative, and the present disclosure is not limited to any one embodiment unless they depart from the concept of the present disclosure.

The display device DD may have a rectangular shape on a plane with short sides extending in a first direction DR1 and long sides extending in a second direction DR2. However, the present disclosure may not be limited thereto, and the display device DD may have various shapes such as a circular or polygonal shape.

The display device DD may display the image in a third direction DR3 via a display surface DS parallel to a surface defined by the first direction DR1 and the second direction DR2. The third direction DR3 may be substantially parallel to a normal direction of the display surface DS. The display surface DS on which the image is displayed may correspond to a front surface of the display device DD. The image may include a static image as well as a dynamic image.

In the present embodiment, a front surface (or a top surface) and a rear surface (or a bottom surface) of each member or unit may be defined based on the direction in which the image is displayed. The front surface and the rear surface may be opposing each other in the third direction DR3, and a normal direction of each of the front surface and the rear surface may be parallel to the third direction DR3. A separation distance between the front surface and the rear surface defined along the third direction DR3 may correspond to a thickness of the member (or the unit). Herein, “on a plane” may be defined as a state viewed in the third direction DR3. Herein, “in a cross-section” may be defined as a state viewed in the first direction DR1 or the second direction DR2. The directions indicated by the first, second, and third directions DR1, DR2, and DR3 are relative concepts and are able to be converted to other directions.

FIG. 1 shows the display device DD having the flat display surface DS as an example. However, the shape of the display surface DS of the display device DD may not be limited thereto, and the display surface DS may be curved or three-dimensional in another embodiment.

The display device DD may be flexible. The “flexible” may refer to a property of being able to bend and may include anything from a completely bendable structure to a structure that may bend at a level of a few nanometers. For example, the flexible display device DD may be a curved device, a foldable device, or a rollable device. Without being limited thereto, the display device DD may be rigid.

The display surface DS of the display device DD may include a display area DA, a non-display area NDA, and a notch area NT. The display area DA may be a portion where the image is displayed within the front surface of the display device DD, and the user may recognize the image via the display area DA. The present embodiment illustrates the display area DA having a rectangular shape as an example, but the display area DA may have various shapes depending on a design.

The non-display area NDA may be a portion where the image is not displayed within the front surface of the display device DD. The non-display area NDA may be a portion having a predetermined color and blocking light. The non-display area NDA may be adjacent to the display area DA. For example, the non-display area NDA may be disposed outside the display area DA and surround the notch area NT and the display area DA. However, this is merely shown as an example, and the non-display area NDA may be adjacent to only one side of the display area DA or may be disposed on a side surface rather than the front surface of the display device DD. The present disclosure may not be limited thereto, and the non-display area NDA may be omitted in another embodiment.

The notch area NT may be an area where a camera module, a speaker module, and/or the like are disposed. In one embodiment, the notch area NT may be omitted. The notch area NT may be a portion where the image is displayed or may be a portion of the front surface where the image is not displayed.

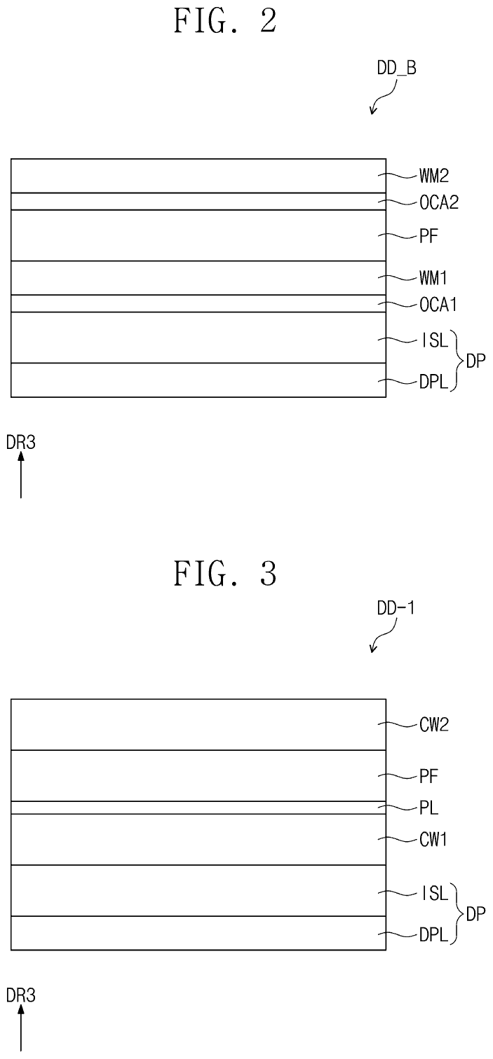

FIG. 2 is a schematic cross-sectional view of a display device DD_B according to Comparative Example of the present disclosure.

Referring to FIG. 2, the display device DD_B may include a display panel DP, a first adhesive layer OCA1, a first window WM1, an optical film PF, a second adhesive layer OCA2, and a second window WM2. In one embodiment of the present disclosure, some of the above-described components may be omitted or other components may be further added.

The display panel DP may include a display layer DPL and a sensor layer ISL disposed on the display layer DPL. The display layer DPL may be a component that actually creates the image. The display layer DPL may be a light-emitting display layer. For example, the display layer DPL may be an organic light-emitting display layer, an inorganic light-emitting display layer, an organic-inorganic light-emitting display layer, a quantum dot display layer, a micro LED display layer, or a nano LED display layer.

The sensor layer ISL may be disposed on the display layer DPL. The sensor layer ISL may sense an external input applied from the outside. The sensor layer ISL may be an external sensor attached to the display layer DPL or the sensor layer ISL may be an integrated sensor formed continuously during a manufacturing process of the display layer DPL.

The first window WM1 may be disposed on the display panel DP. The first window WM1 may reinforce a strength of the display device DD_B. The first window WM1 may contain an optically transparent insulating material. For example, the first window WM1 may contain glass or plastic. The first adhesive layer OCA1 may be disposed between the first window WM1 and the display panel DP to bond the first window WM1 with the display panel DP.

The optical film PF may be disposed on the first window WM1. The optical film PF may lower a reflectance of light incident from the outside. The optical film PF may include a phase retarder and/or a polarizer. The optical film PF may include at least a polarizing film. In this case, although not shown in FIG. 2, the optical film PF may be attached to the first window WM1 via an adhesive layer.

Alternatively, the optical film PF may include color filters. The color filters may have a predetermined arrangement. The arrangement of the color filters may be determined by considering colors of light emitted from pixels included in the display layer DPL. Additionally, the optical film PF may further include a black matrix adjacent to the color filters. In this case, the adhesive layer between the optical film PF and the first window WM1 may be omitted.

Alternatively, the optical film PF may include a destructive interference structure. For example, the destructive interference structure may include a first reflective layer and a second reflective layer disposed on different layers. First reflected light and second reflected light reflected from the first reflective layer and the second reflective layer, respectively, may cause destructive interference therebetween, and thus the reflectance of external light may be reduced. In this case, the adhesive layer between the optical film PF and the first window WM1 may be omitted.

The second window WM2 may be disposed on the optical film PF. The second window WM2 may contain an optically transparent insulating material. For example, the second window WM2 may contain glass or plastic. The second window WM2 may have a multi-layer structure or a single-layer structure. For example, the second window WM2 may include a plurality of plastic films bonded together with an adhesive or may include a glass substrate and a plastic film bonded together with the adhesive. The second adhesive layer OCA2 may be disposed between the second window WM2 and the optical film PF to bond the second window WM2 with the optical film PF.

The first and second adhesive layers OCA1 and OCA2 may be an optically clear adhesive (OCA) or a pressure sensitive adhesive film (PSA film), but may not be particularly limited thereto.

FIG. 3 is a schematic cross-sectional view of a display device DD-1 according to an embodiment of the present disclosure. In describing FIG. 3, the description will be made with reference to FIG. 2, and description of the same reference numerals will be omitted.

Referring to FIG. 3, the display device DD-1 may include: the display panel DP, a protective substrate (or a first coating member) CW1, the optical film PF, and a window (or a second coating member) CW2. In one embodiment of the present disclosure, some of the above-described components may be omitted or other components may be further added.

The protective substrate CW1 may be disposed on the display panel DP. The protective substrate CW1 may be a component corresponding to the first window WM1 in FIG. 2. The protective substrate CW1 in FIG. 3 may replace the first window WM1 and the first adhesive layer OCA1 in FIG. 2. That is, in the display device DD-1 according to one embodiment of the present disclosure, the first adhesive layer OCA1 may be omitted. The protective substrate CW1 may include an optically transparent insulating material. The protective substrate CW1 may include a UV-curable resin or a thermosetting resin. However, this is exemplary, and the material of the protective substrate CW1 according to one embodiment of the present invention may be provided in various ways.

The optical film PF may be disposed on the protective substrate CW1. A protective layer PL may be disposed between the optical film PF and the protective substrate CW1. The protective layer PL may contain polyethylene terephthalate (“PET”).

The window CW2 may be disposed on the optical film PF. The window CW2 may be a component corresponding to the second window WM2 in FIG. 2. The window CW2 in FIG. 3 may replace the second window WM2 and the second adhesive layer OCA2 in FIG. 2. That is, in the display device DD-1 according to one embodiment of the present disclosure, the second adhesive layer OCA2 may be omitted.

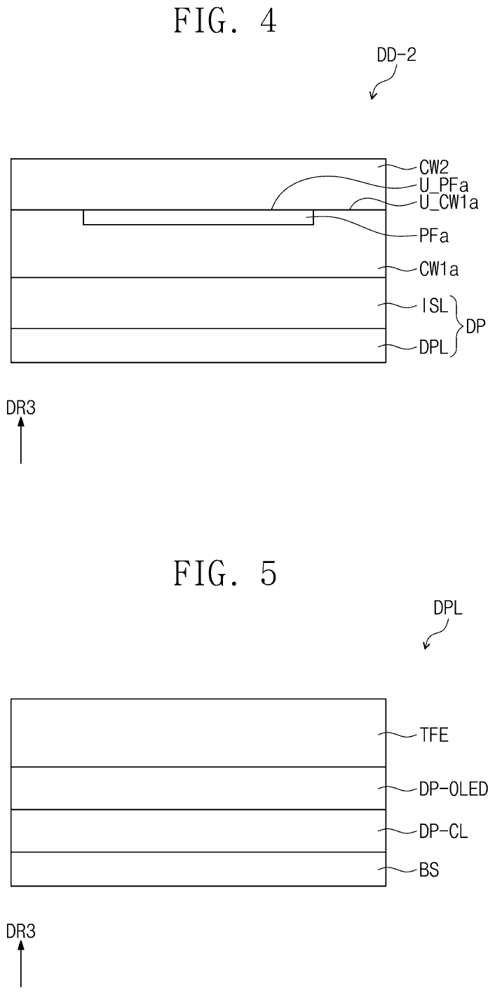

FIG. 4 is a schematic cross-sectional view of a display device DD-2 according to another embodiment of the present disclosure. In describing FIG. 4, the description will be made with reference to FIGS. 2 and 3, and description of the same reference numerals will be omitted.

Referring to FIG. 4, the display device DD-2 may include the display panel DP, a protective substrate (or a first coating member) CW1a, an optical film PFa, and the window (or the second coating member) CW2. In one embodiment of the present disclosure, some of the above-described components may be omitted, or other components may be further added.

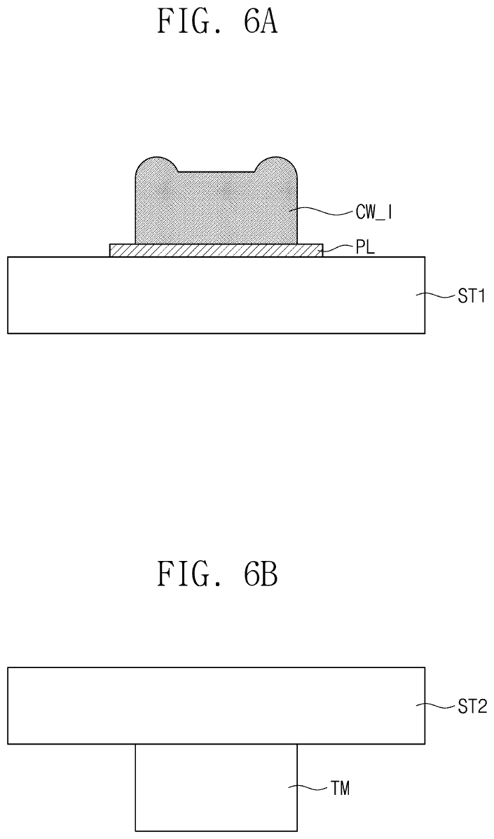

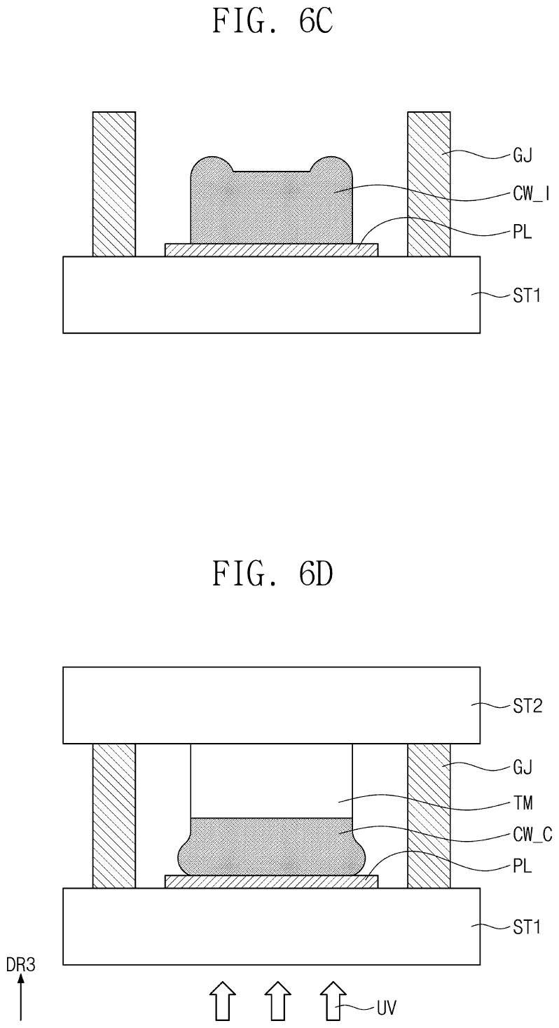

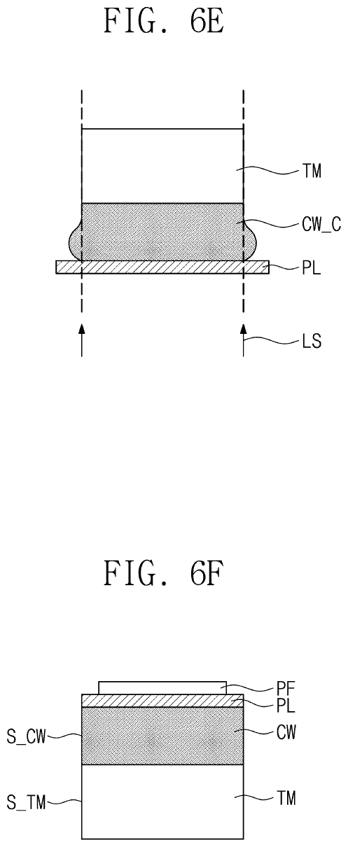

The protective substrate CW1a may be disposed on the display panel DP, and the optical film PFa may be disposed on the protective substrate CW1a. A top surface U_CW1a of the protective substrate CW1a may be aligned with a top surface U_PFa of the optical film PFa. Additionally, a side surface of the protective substrate CW1a may be aligned with a side surface of the display panel DP. In a display device manufacturing process to be described later, a preliminary protective substrate CW_C (see FIG. 6D) may be cut such that the side surface of the display panel DP may be aligned with the side surface of the protective substrate CW1a. Details will be described later. In the embodiment of FIG. 4, the protective substrate CW1a may be directly bonded with the display panel DP and the optical film PFa.

In one embodiment, the window CW2 may be disposed on the optical film PFa and the protective substrate CW1a. However, this is merely illustrative, and the second adhesive layer OCA2 (see FIG. 2) and the second window WM2 may be disposed on the optical film PFa and the protective substrate CW1a in another embodiment.

FIG. 5 is a cross-sectional view of the display panel DP according to an embodiment of the present disclosure.

Referring to FIG. 5, the display panel DP may include a base substrate BS, a circuit element layer DP-CL, an element layer DP-OLED, and an encapsulation layer TFE. The display panel DP may actually create the image. The display panel DP may be the light-emitting display panel. For example, the display panel DP may be the organic light-emitting display panel, the inorganic light-emitting display panel, the organic-inorganic light-emitting display panel, the quantum dot display panel, the micro LED display panel, or the nano LED display panel.

The base substrate BS may be a member that provides a base surface on which the circuit element layer DP-CL is disposed. The base substrate BS may be a polymer substrate. For example, the base substrate BS may be a polyimide substrate. However, the embodiment may not be limited thereto, and the base substrate BS may be an inorganic layer, an organic layer, or a composite material layer in another embodiment.

The circuit element layer DP-CL may be disposed on the base substrate BS. The circuit element layer DP-CL includes a driving circuit of a unit pixel or a signal line. The element layer DP-OLED may be disposed on the circuit element layer DP-CL. The element layer DP-OLED may include a light-emitting element disposed for each unit pixel.

The encapsulation layer TFE may protect the circuit element layer DP-CL from moisture, oxygen, and foreign substances such as dust particles. The encapsulation layer TFE may include at least one inorganic layer and one organic layer. The inorganic layer may protect the circuit element layer DP-CL from moisture and oxygen, and the organic layer may protect the circuit element layer DP-CL from the foreign substances such as the dust particles.

FIGS. 6A to 6F are cross-sectional views showing some of steps of a display device manufacturing method according to an embodiment of the present disclosure. In describing FIGS. 6A to 6F, the same/similar components will be described using the same/similar reference numerals with reference to FIGS. 1 to 5, and duplicate descriptions will be omitted. A portion of the display device formed via FIGS. 6A to 6F may correspond to the display device DD-1 in FIG. 3.

Referring to FIG. 6A, the display device manufacturing method of the present disclosure may include providing a first stage ST1 and forming a coating material CW_I on the first stage ST1.

The first stage ST1 provided in the present disclosure may contain a transparent material. The first stage ST1 may be disposed at the bottom during the display device manufacturing process and may provide a space for various components/parts to be disposed. The display device manufacturing method of the present disclosure may further include forming the protective layer PL containing polyethylene terephthalate (PET) on the first stage ST1.

Thereafter, the coating material CW_I may be formed on the first stage ST1. Specifically, the coating material CW_I may be provided on the protective layer PL. Because the coating material CW_I is cut in a process to be described later, the coating material CW_I does not need to be formed precisely. That is, required precision necessary for forming the coating material CW_I may be low.

Thereafter, referring to FIG. 6B, the display device manufacturing method of the present disclosure may include adsorbing a target member TM on a second stage ST2.

The second stage ST2 provided in the present disclosure may be disposed at the top during the display device manufacturing process and may adsorb and move components/parts. The target member TM may be adsorbed onto the second stage ST2. Specifically, the target member TM may be moved by being adsorbed to a bottom surface of the second stage ST2. The target member TM may be the display panel DP or the optical film PF in FIG. 3.

Thereafter, referring to FIGS. 6C and 6D, the display device manufacturing method of the present disclosure may include forming a jig GJ on the first stage ST1 and placing the second stage ST2 on the jig GJ.

The jig GJ may be formed to face side surfaces of the protective layer PL and the coating material CW_I, and the jig GJ may serve to support the second stage ST2. The target member TM adsorbed by the second stage ST2 may be disposed on the coating material CW_I. The second stage ST2 may be disposed on the jig GJ such that the target member TM and the coating material CW_I overlap each other.

The forming of the jig GJ on the first stage ST1 may include setting a height of the jig GJ to be the same as or greater than a sum of a thickness of a preliminary coating member CW_C and a thickness of the target member TM in the third direction DR3. A shape of the coating material CW_I may be changed by the second stage ST2 seated on the jig GJ. For example, a thickness of the coating material CW_I may be reduced and the coating material CW_I may spread widely on the protective layer PL. Thereafter, when the coating material CW_I is cured, the sum of the thickness of the preliminary coating member CW_C, the thickness of the target member TM and the protective layer PL may correspond to the height of the jig GJ. In other words, the thickness of the preliminary coating member CW_C and the thickness of the target member TM may be adjusted by the height of the jig GJ.

Referring to FIG. 6D, the display device manufacturing method of the present disclosure may include forming the preliminary coating member CW_C by curing the coating material CW_I (see FIG. 6C). The forming of the preliminary coating member CW_C by curing the coating material CW_I may include irradiating an ultraviolet laser UV toward the first stage ST1. The ultraviolet laser UV irradiated toward the first stage ST1 may pass through the first stage ST1 and cure the coating material CW_I. Thereafter, the first stage ST1 and the second stage ST2 may be removed.

Referring to FIGS. 6E and 6F, the display device manufacturing method of the present disclosure may include cutting the preliminary coating member CW_C to form a coating member CW. The cutting of the preliminary coating member CW_C to form the coating member CW may include cutting a portion of the preliminary coating member CW_C protruding from a side surface of the target member TM. That is, the preliminary coating member CW_C may be cut such that a side surface S_TM of the target member TM may be aligned with a side surface S_CW of the coating member CW.

In the cutting of the preliminary coating member CW_C to form the coating member CW, a laser LS may be irradiated toward the protective layer PL. The laser LS may cut the preliminary coating member CW_C. The laser LS may be irradiated considering a shape in a plane. For example, the laser LS may be irradiated to have a rounded corner of the display device DD in FIG. 1 or to correspond to the notch area NT. Thereafter, the coating member CW and the target member TM may be turned upside down.

In one embodiment, the target member TM may be the optical film PF in FIG. 3, and the coating member CW may be the window CW2 in FIG. 3. The window CW2 may be formed on the optical film PF without the adhesive layer.

In another embodiment of the present disclosure, the display device manufacturing method may further include forming the optical film PF on the coating member CW. Specifically, the optical film PF may be formed on the protective layer PL. In this case, the target member TM may be the display panel DP in FIG. 3, and the coating member CW may be the protective substrate CW1 in FIG. 3.

That is, the protective substrate CW1 and the window CW2 in FIG. 3 may be formed via the curing process of the coating member CW in FIGS. 6A to 6F. In the display device manufacturing method, both the protective substrate CW1 and the window CW2 may be formed via the curing process of the coating member CW in FIGS. 6A to 6F, or in the display device manufacturing method, only one of the protective substrate CW1 and the window CW2 may be formed via the curing process of the coating member CW in FIGS. 6A to 6F.

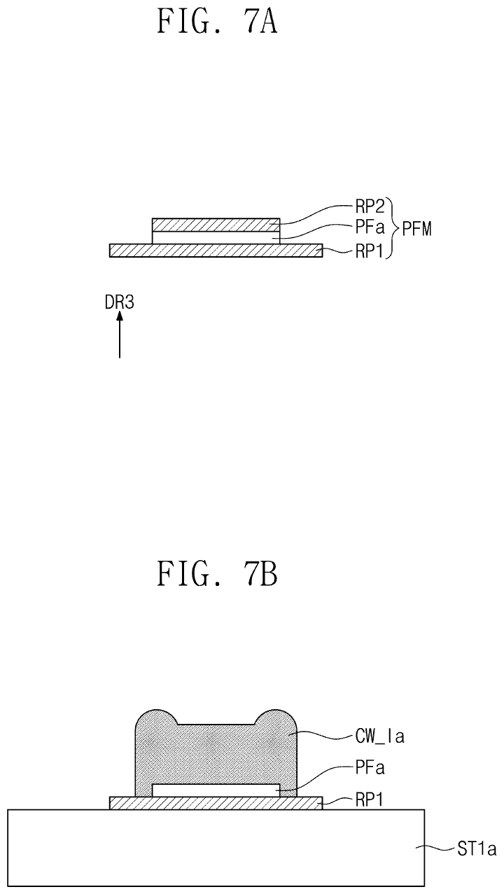

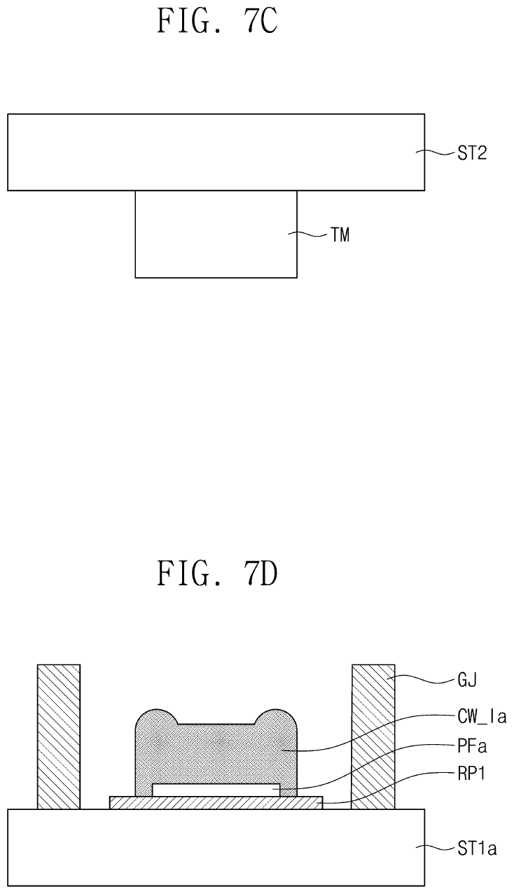

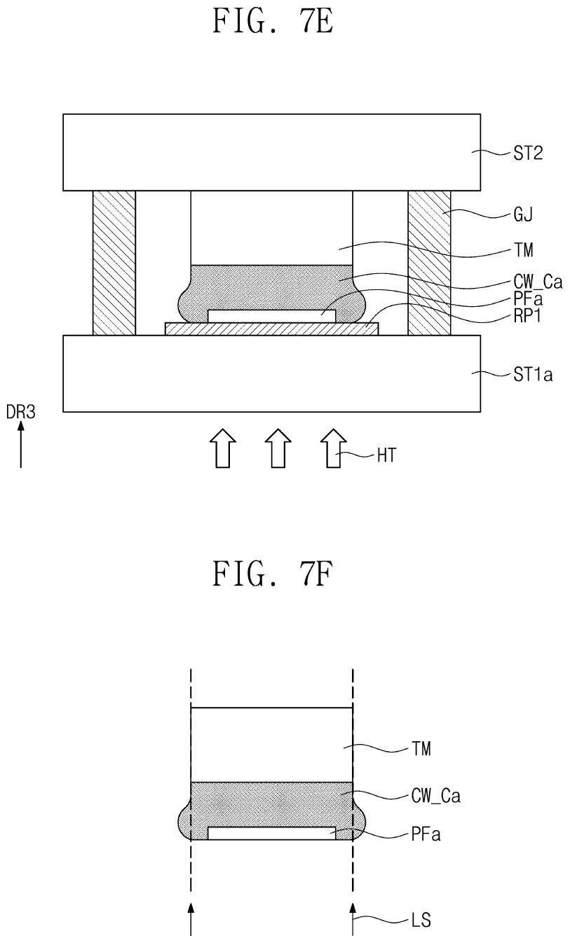

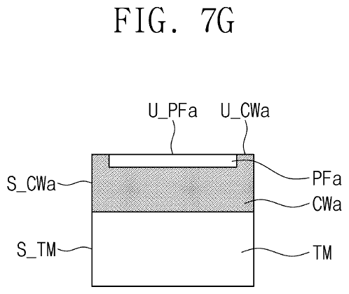

FIGS. 7A to 7G are cross-sectional views showing some of steps of a display device manufacturing method according to an embodiment of the present disclosure. In describing FIGS. 7A to 7G, the same/similar components will be described using the same/similar reference numerals with reference to FIGS. 1 to 6F, and duplicate descriptions will be omitted. A portion of the display device formed via FIGS. 7A to 7G may correspond to the display device DD-2 in FIG. 4.

Referring to FIG. 7A, the display device manufacturing method of the present disclosure may include preparing an optical film member PFM. The optical film member PFM may include a first release film RP1, the optical film PFa, and a second release film RP2 sequentially stacked along the third direction DR3. An adhesive layer may be disposed between the first release film RP1 and the optical film PFa to bond the first release film RP1 with the optical film PFa. A width of the first release film RP1 in one direction (e.g., the first direction DR1 (see FIG. 1) or the second direction DR2 (see FIG. 1)) may be greater than a width of the optical film PFa in the one direction (e.g., the first direction DR1 (see FIG. 1) or the second direction DR2 (see FIG. 1)).

Referring to FIG. 7B, the display device manufacturing method of the present disclosure may include providing a first stage ST1a. The first stage ST1a provided in the present disclosure may contain a heat-conducting material. The first stage ST1a may be disposed at the bottom during the display device manufacturing process and may provide a space for various components/parts to be disposed.

Thereafter, the display device manufacturing method of the present disclosure may include removing the second release film RP2 and placing the first release film RP1 and the optical film PFa on the first stage ST1a. Additionally, forming a coating material CW_Ia on the first stage ST1a may be included. Specifically, the coating material CW_Ia may be deposited on the first release film RP1 to cover a front surface of the optical film PFa. Because the coating material CW_Ia is cut in a process to be described later, the coating material CW_Ia may not be formed precisely. In other words, required precision necessary for forming the coating material CW_Ia may be low.

Thereafter, referring to FIG. 7C, the display device manufacturing method of the present disclosure may include adsorbing the target member TM on the second stage ST2.

The second stage ST2 provided in the present disclosure may be disposed at the top during the display device manufacturing process and may adsorb and move components/parts. The target member TM may be adsorbed onto the second stage ST2. Specifically, the target member TM may be moved by being adsorbed to the bottom surface of the second stage ST2. The target member TM may be the display panel DP in FIG. 4.

Thereafter, referring to FIGS. 7D and 7E, the display device manufacturing method of the present disclosure may include forming the jig GJ on the first stage ST1a and placing the second stage ST2 on the jig GJ.

The jig GJ may be formed to face side surfaces of the first release film RP1 and the optical film PFa, and the jig GJ may play a role in supporting the second stage ST2. The target member TM adsorbed by the second stage ST2 may be disposed on the coating material CW_Ia. The second stage ST2 may be disposed on the jig GJ such that the target member TM and the coating material CW_Ia overlap each other.

The forming of the jig GJ on the first stage ST1a may include setting the height of the jig GJ to be the same as or greater than a sum of a thickness of a preliminary coating member CW_Ca (see FIG. 7E) and the thickness of the target member TM in the third direction DR3. A shape of the coating material CW_Ia may be changed by the second stage ST2 mounted on the jig GJ. For example, a thickness of the coating material CW_Ia may be reduced and the coating material CW_Ia may spread widely on the first release film RP1. Specifically, the coating material CW_Ia may cover the optical film PFa and may be spread widely on a first release film RP1. Thereafter, when the coating material CW_Ia is cured, a sum of the thickness of the preliminary coating member CW_Ca, the thickness of the target member TM and a thickness of the first release film RP1 may correspond to the height of the jig GJ. In other words, the thickness of the preliminary coating member CW_Ca and the thickness of the target member TM may be adjusted by the height of the jig GJ.

Referring to FIG. 7E, the display device manufacturing method of the present disclosure may include forming the preliminary coating member CW_Ca by curing the coating material CW_Ia (see FIG. 7D). The forming of the preliminary coating member CW_Ca by curing the coating material CW_Ia may include supplying heat to the first stage ST1a. The heat supplied toward the first stage ST1a may be transferred to the coating material CW_Ia by the first stage ST1a, which has heat-conducting properties, and may cure the coating material CW_Ia. Thereafter, the first stage ST1a and the second stage ST2 may be removed. Additionally, after forming the preliminary coating member CW_Ca, the display device manufacturing method may further include removing the first release film RP1.

Referring to FIGS. 7F and 7G, the display device manufacturing method of the present disclosure may include cutting the preliminary coating member CW_Ca to form a coating member CWa. The cutting of the preliminary coating member CW_Ca to form the coating member CWa may include cutting a portion of the preliminary coating member CW_Ca protruding from the side surface of the target member TM. That is, the preliminary coating member CW_Ca may be cut such that the side surface S_TM of the target member TM may be aligned with a side surface S_CWa of the coating member CWa.

In the cutting of the preliminary coating member CW_Ca to form the coating member CWa, the laser LS may be irradiated toward the preliminary coating member CW_Ca. The laser LS may cut the preliminary coating member CW_Ca. The laser LS may be irradiated considering the shape in the plane. For example, the laser LS may be irradiated to have the rounded corner of the display device DD in FIG. 1 or to correspond to the notch area NT. In this case, the top surface U_PFa of the optical film PFa may be aligned with a top surface U_CWa of the coating member CWa. That is, the optical film PFa may be formed without protruding from the coating member CWa. Thereafter, the coating member CWa and the target member TM may be turned upside down.

In one embodiment of the present disclosure, the target member TM may be the display panel DP in FIG. 4, and the coating member CWa may be the protective substrate CW1a in FIG. 4. That is, the protective substrate CW1a in FIG. 4 may be formed via the curing process of the coating member CWa in FIGS. 7A to 7G.

According to the present disclosure, a thickness of the coating member CW or CWa may be constant. For example, a difference in level between a central portion and an edge of the coating member CW or CWa may be reduced or eliminated. As the coating member CW or CWa is formed flat, reliability of the display device DD-1 or DD-2 may be effectively improved. Additionally, when curing the coating material and cutting the coating material with the laser to form the protective substrate CW1 or the window CW2, the required precision necessary for forming the coating material may be low, the process may be simplified, and the cost may be reduced.

Although the description has been made with reference to a preferred embodiment of the present disclosure, those skilled in the art or have ordinary knowledge in the relevant technical field will understand that the present disclosure may be modified and changed in various ways without departing from the ideas and the technical scope of the present disclosure described in the claims to be described later. Therefore, the technical scope of the present disclosure should not be limited to the content described in the detailed description of the present document, but should be determined by the claims.

What is claimed is:

1. A method for manufacturing a display device, the method comprising:
providing a first stage;
forming a coating material on the first stage;
adsorbing a target member onto a second stage;
forming a jig on the first stage;
placing the second stage on the jig;
curing the coating material to form a preliminary coating member; and
cutting the preliminary coating member to form a coating member.

2. The method of claim 1, wherein the forming of the jig on the first stage includes:
setting a height of the jig to be the same as or greater than a sum of a thickness of the preliminary coating member and a thickness of the target member.

3. The method of claim 1, wherein the cutting of the preliminary coating member to form the coating member includes:
cutting a portion of the preliminary coating member protruding from a side surface of the target member.

4. The method of claim 1, wherein the first stage contains a transparent material.

5. The method of claim 1, further comprising:
forming a protective layer containing polyethylene terephthalate (PET) on the first stage.

6. The method of claim 1, wherein the curing of the coating material to form the preliminary coating member includes:
irradiating ultraviolet (UV) laser toward the first stage.

7. The method of claim 1, wherein the target member is a display panel, and the coating member is a protective substrate.

8. The method of claim 7, wherein the cutting of the preliminary coating member to form the coating member includes:
cutting the preliminary coating member such that a side surface of the display panel is aligned with a side surface of the protective substrate.

9. The method of claim 7, further comprising:
forming an optical film on the coating member.

10. The method of claim 1, wherein the target member is an optical film, and the coating member is a window.

11. The method of claim 10, wherein the cutting of the preliminary coating member to form the coating member includes:
cutting the preliminary coating member such that a side surface of the optical film is aligned with a side surface of the window.

12. The method of claim 1, wherein the first stage contains a heat-conducting material.

13. The method of claim 1, further comprising:
preparing an optical film member including a first release film, an optical film, and a second release film, which are sequentially stacked,
removing the second release film and placing the first release film and the optical film on the first stage,
wherein a width in one direction of the first release film is greater than a width in the one direction of the optical film.

14. The method of claim 13, further comprising:
forming the preliminary coating member and then removing the first release film.

15. The method of claim 13, wherein the forming of the coating material on the first stage includes:
depositing the coating material to cover a front surface of the optical film.

16. The method of claim 13, wherein a top surface of the optical film is aligned with a top surface of the coating member.

17. The method of claim 1, wherein the curing of the coating material to form the preliminary coating member includes:
supplying heat to the first stage.

18. A display device comprising:
a display panel;
a protective substrate disposed on the display panel; and
an optical film disposed on the protective substrate,
wherein a top surface of the protective substrate is aligned with a top surface of the optical film.

19. The display device of claim 18, wherein a side surface of the protective substrate is aligned with a side surface of the display panel.

20. The display device of claim 18, wherein the protective substrate is directly bonded with the display panel and the optical film.
